(19) United States
(12) Patent Application Publication
(10) Pub. No.: US 2012/0206304 A1
(43) Pub. Date: Aug. 16, 2012

(54) HYBRID REFLECTOMETER SYSTEM (HRS)

(75) Inventors: Nathan Clow, Salisbury (GB); Stephen John Perkins, Salisbury (GB); Ivor Leslie Morrow, Swindon (GB)

(73) Assignee: The Secretary Of State For Defence, Salisbury, Wiltshire (GB)

(21) Appl. No.: 13/391,823

(22) PCT Filed: Aug. 18, 2010
(86) PCT No.: PCT/GB10/01558

§ 371 Date: Feb. 23, 2012

(30) Foreign Application Priority Data
Aug. 26, 2009 (GB) 0914926.1

(51) Int. Cl. G01R 29/08

(52) U.S. Cl. 343/703

(57) ABSTRACT

A RF signal test and measurement system capable of measuring forward and reverse signal parameters of RF components including Electrically Small Antennas (ESA) and capable of being integrated within a communications system to aid the automatic retuning of antennas.

### TECHNICAL FIELD OF THE INVENTION

This invention relates to a Radio Frequency (RF) signal test and measurement system capable of measuring forward and reverse signal parameters of RF components including antennas and particularly including Electrically Small Antennas (ESA) and more particularly relates to a RF test and measurement system capable of being integrated within a communications system to aid the automatic retuning of antennas.

### BACKGROUND TO THE INVENTION

It is necessary when developing RF equipment to test the RF components such as antennas to verify their actual performance either independently or within an integrated system. Measuring antenna performance is often achieved by connecting an antenna to a reflectometer. This allows a person to measure the Scattering parameter (S-parameter) magnitudes of the antenna using a network analyser, but calibration to allow for unpredictable losses from radiating devices is problematic. This is especially problematic for ESA because the energy reflected back from the antenna acts as a common mode current returning to the measurement system. This unpredictable effect cannot be accounted for in the calibration procedure.

Antennas which are embedded in hosts such as a mobile phone are generally electrically small. An electrically small antenna is usually considered to mean that the antenna has no dimension larger than λ/10 when operating at its highest operational frequency. Furthermore these embedded ESA are sensitive to the surrounding environment and vulnerable to detuning. During testing for example if the measurement system is placed too close to the antenna, it can act as a parasitic element due to the use of components like a RF input cable. Consequently, communicating with the host in different environments becomes extremely difficult due to this detuning effect.

There are several methods for using a measurement system to measure radiation efficiency of ESA. Pattern integration is by far the most precise method currently used for measuring the absolute radiation efficiency of an ESA. However, it is the most convoluted and time consuming method, requiring a calibrated range or anechoic chamber. It is difficult to implement in practice at frequencies below 500 MHz. The method is further complicated if the far field of the antenna has a complex pattern or complicated polarisation.

The Q factor method uses a theoretical value for the quality factor of a lossless antenna; this can be difficult to obtain if the antenna is anything but a simple structure. It also assumes that the form of current distribution on the antenna remains unchanged when a change is made in the antenna or its surroundings.

The resistance comparison method requires two antennas to be constructed that are identical but with differing metals. The difference in conductivity of the two metals is presumed to be a small perturbation and their ohmic resistances are assumed to differ. The method also assumes that the conductivity of the metals and the operating frequency are high. These assumptions are made so that the concept of surface resistance can be used to determine the radiation resistance. Furthermore, as with the Q factor method, this method also assumes that the form of current distribution on the antenna remains unchanged when a change is made in the antenna or its surroundings.

The radiometric method is based on the principle that a lossy antenna directed at an area of low noise will generate more noise power than a lossless antenna directed at the same area. The loss in the antenna can be seen as a noise source at the ambient temperature. The method is not suitable for antennas which have nominally omni-directional radiation patterns such as ESA. When directed to an area of low noise (i.e. the sky at zenith), such antennas receive radiation from the horizon which may be much hotter thus increasing measurement uncertainty. The method is therefore useful for high-gain antennas with pencil-beam type radiation patterns. The method also requires a high quality amplifier and mixer with good noise figures, which must be mounted close to the antenna to avoid additional components which would add noise. Amplifiers which are prone to drift add to measurement uncertainty. Furthermore, the antenna must be impedance matched to the source to avoid increasing system noise.

The Random Field Measurement (RFM) method is based on a statistical theory which assumes the signal received by an unknown antenna and a reference antenna follows the Rayleigh distribution. The technique is used to measure the radiation efficiency of an antenna when in close proximity to a human body. The statistical nature of the measurement procedure leads to it being more time consuming than other conventional methods.

The calorimetric method is based on the measurement of the power dissipated rather than the power radiated. It is reported to be a low-cost alternative for the pattern integration and a replacement of the Wheeler cap method described below. However, the measurement procedure is more complicated than the Wheeler cap method. Although the equipment needed for the measurement is relatively less expensive than for the pattern integration method, it is still considerably more expensive than using the Wheeler cap method.

The reverberation chamber method is stated to be a less expensive alternative to the pattern integration method. Mode and platform stirring is used to setup a multi-path environment inside a metallic chamber. Statistical analysis is then used to determine the radiation efficiency of an antenna. The modes inside the chamber are modulated by a metallic paddle which is rotated at a constant and known velocity. To obtain improved measurement accuracy the antenna under test, also referred to as the platform, is also rotated. The method is based on the premise that the average received power in a reverberation chamber is proportional to the radiation efficiency of the test antenna.

The reflection method examines the reflection coefficient of the antenna when the distance between the antenna and reflecting short is varied. The measurement is performed in a rectangular waveguide operating the transverse electric TE10 mode. This method can be regarded as an extension to the Wheeler Cap method, however, the procedure is far more complicated and requires a somewhat complicated waveguide setup with high quality sliding shorts. The added benefit is that the antenna loss is modelled whether they consist of a series resistor, parallel conductance or non-simple antenna structures.

The radiation shield method is a concept of a radiation shield in the form of a conducting shell the size of a radian sphere which originates from a paper published by H. Wheeler in 1959 (“The radiansphere around a small antenna,” proceedings IREE Australia, vol. 47, pp. 1325-1331, August 1959) in which he states that, for an electrically small antenna, the radiation shield enables a separate measurement of radiation resistance and loss resistance. This method of measuring the radiation efficiency is now known as the classic Wheeler Cap method and is widely used as it is easy to implement in practice requiring only two measurements of the input impedance. The Wheeler Cap method is modelled on an equivalent series RLC circuit, which may not be the case for all antennas such as microstrip antennas. Consequently, a modified Wheeler Cap method was presented by W. McKinze (“A modified wheeler cap method for measuring antenna efficiency,” IEEE Antennas and Propagation Society International Symposium, vol. 4, pp. 542-545, July 1997) which approximates the input impedance of an antenna near resonance with either a series or parallel RLC circuit model. In this method, the antenna is placed in a conducting sphere or hemisphere with the antenna placed on a ground plane. The sphere is known as a “Wheeler cap” and is used to prevent radiation by ensuring that all the radiated energy is reflected thus the measured impedance is due to the losses in the antenna. Previously Wheeler cap measurements have been difficult due to the RF interference present at the input and output of the measurement system. The invention aims to isolate the RF component being measured and hence accuracy of the signal measurements is greatly improved.

### SUMMARY OF THE INVENTION

It is an object of the present invention to provide an electrically small reflectometer RF test and measurement system (referred to herein as a Hybrid Reflectometer System or HRS due to the digital and analogue components used) capable of measuring forward and reverse signal parameters of RF components including ESA but isolated from the component in such a way as to prevent parasitic effects. It is also an object that the HRS can be integrated into a communications system for example an antenna system to enable the retuning of antennas when operated within a variety of conditions and environments.

Accordingly the present invention provides a test and measurement system for measuring radio frequency signals transmitted or received by an electrically small radiating element comprising an electrically small reflectometer wherein the output from the electrically small reflectometer is provided in the form of an optical digital signal.

An electrically small reflectometer is used here to mean that the reflectometer is electrically smaller than the electrically small radiating element such as an ESA. Currently within the state of the art, the output from a reflectometer has always been an analogue signal. A network analyser for example will take the analogue signal and process it further before converting the signal to a digital format. This means that on the output of the reflectometer there are RF components which can interfere with the measurement of a signal by the reflectometer. The result is that error correction has to be introduced. By converting the output from the electrically small reflectometer immediately to a digital signal the invention can prevent RF interference of the signal being measured and hence increase accuracy. This therefore removes the need for error correction. One method of achieving this is to construct the electrically small reflectometer with a radio frequency dual directional coupler and electronically connect it to an analogue to digital converter.

Preferably by taking the digital signal output and transmitting it through an Optical Data Transmitter module, the digital signal relating to the antenna can be converted to optical format. The output of the Optical Data Transmitter module can be transmitted to a personal computer (PC) via an Optical Data Receiver (fibre optic link). This ensures that the antenna signals can be analysed using the PC without a RF cable being used. Also if an Optical to RF module is added to the input of the electrically small reflectometer then a fibre optic cable can input signals into the Optical to RF module, eliminating the need for a RF feed cable. This allows measurements of the forward and reverse antenna transfer characteristics to be carried out without compromising the RF properties of the antenna. In other words the antenna is now completely isolated from both input and output RF interference and so accuracy of the measurements will be further improved.

The invention can be used within an anechoic chamber or a Wheeler cap to measure radio frequency signals without the use of RF feed cables which eliminates adverse RF effects from the measurements being taken. A person skilled in the art will appreciate that the invention can be used with other measurement techniques such as those described previously.

The invention can beneficially be used with a RF device such as a RF amplifier or filter to provide impedance matching measurements of that device which would be useful within a feed-back loop.

A RF measurement system capable of measuring both the forward and reverse signal parameters at the terminal of the RF component to significantly reduce the effects of the common mode current during the measurement process and without the system acting parasitically could be integrated into a feedback loop of a communications system. The measurement system would be able to detect signal errors occurring due to environmental changes affecting the antenna and input the detected errors into a device such as an Automatic Antenna Matching Unit (AAMU) to aid with the automatic retuning of the antenna.

### BRIEF DESCRIPTION OF THE DRAWINGS

The invention will now be described, by way of example, with reference to the accompanying drawings, in which:

FIG. 1 shows the HRS system network diagram;

FIG. 2 shows a simplified HRS system network diagram;

FIG. 3 shows the HRS signal flow chart diagram;

FIG. 4 shows the HRS system component diagram;

FIG. 5 shows the HRS characterisation set-up for measuring power transmitted in the forward direction;

FIG. 6 shows the measured reflection coefficient of the HRS;

FIG. 7 shows the measured transmission coefficient of the HRS;

FIG. 8 shows the HRS scattering parameter set-up;

FIG. 9 shows the linearity of the output data power to the input power in the forward direction;

FIG. 10 shows the linearity of the output data power to the input power in the reverse direction;

FIG. 11 shows the calibration set-up for port 1 of the HRS including the RF to fibre optic module for system characterisation;

FIG. 12 shows the calibration set-up for port 2 of the HRS including the RF to fibre optic module for system characterisation;

FIG. 13 shows the calibration set-up for port 1 of the HRS for measuring return loss;

FIG. 14 shows the calibration set-up for port 2 of the HRS for measuring return loss;

FIG. 15 illustrates the HRS integrated into an antenna radiation measurement system;

FIG. 16 provides a radiation plot of a calibrated dipole antenna;

FIG. 17 provides a radiation plot for a monopole (M1) antenna;

FIG. 18 provides a radiation plot for a monopole (M3) antenna;

FIG. 19 provides a radiation plot for the M2 monopole antenna;

FIG. 20 provides a radiation plot for the ESP antenna;

FIG. 21 is a system diagram of the HRS integrated into a Wheeler Cap measurement system;

FIG. 22 shows the reflection coefficient of the M1 antenna placed in free space;

FIG. 23 shows the reflection coefficient of the M1 antenna placed in the Wheeler Cap Measurement system;

FIG. 24 shows the reflection coefficient of the M3 antenna placed in free space;

FIG. 25 shows the reflection coefficient of the M3 antenna placed in the Wheeler Cap Measurement system;

FIG. 26 shows the reflection coefficient of the M2 antenna placed in free space;

FIG. 27 shows the reflection coefficient of the M2 antenna placed in the Wheeler Cap Measurement system;

FIG. 28 shows the reflection coefficient of the ESP antenna placed in free space;

FIG. 29 shows the reflection coefficient of the ESP antenna placed in the Wheeler Cap Measurement system;

FIG. 30 is a system diagram of the HRS integrated into a system where a beacon controls an AAMU.

FIG. 31 is a system diagram of the HRS integrated into a system where the beacon controls a reconfigurable antenna.

FIG. 32 is a system diagram of the HRS integrated into a system where the beacon controls the AAMU and reconfigurable antenna.

### DETAILED DESCRIPTION

FIG. 1 shows the signal flow network analysis of the HRS which can be used to reduce complicated networks to relatively simple input-output relations. The RF network may then be characterised using scattering parameters. This technique is used to analyse the HRS and obtain the system's scattering parameters. For the network analysis the HRS consists of four modules; each module is a two-port network represented by a block which has two input ports and two output ports. The ports associated with each module are:

### The RF to Optical Module

a1 Input incident signal node
a2 Output reflected signal node
b1 Input reflected signal node
b2 Output incident signal node

### The Optical to RF Module

a3 Input incident signal node
a4 Output reflected signal node
b3 Input reflected signal node
b4 Output incident signal node

### The Dual-Directional Coupler RF (DDC (RF)) Module

a5 Input incident signal node
a6 Output reflected signal node
b5 Input reflected signal node
b6 Output incident signal node

### The Dual-Directional Coupler A/D Converter (DDC (A/D)) Module

a8 Input incident signal node
a9 Output reflected signal node
b8 Input reflected signal node
b9 Output incident signal node

The source, Vs, is connected to the RF to Optical module and has a characteristic impedance and reflection coefficient Zs and Γs, respectively. The antenna is connected to the DDC (RF) module and has a characteristic impedance and reflection coefficient Z_{A} and Γ_{A}, respectively.

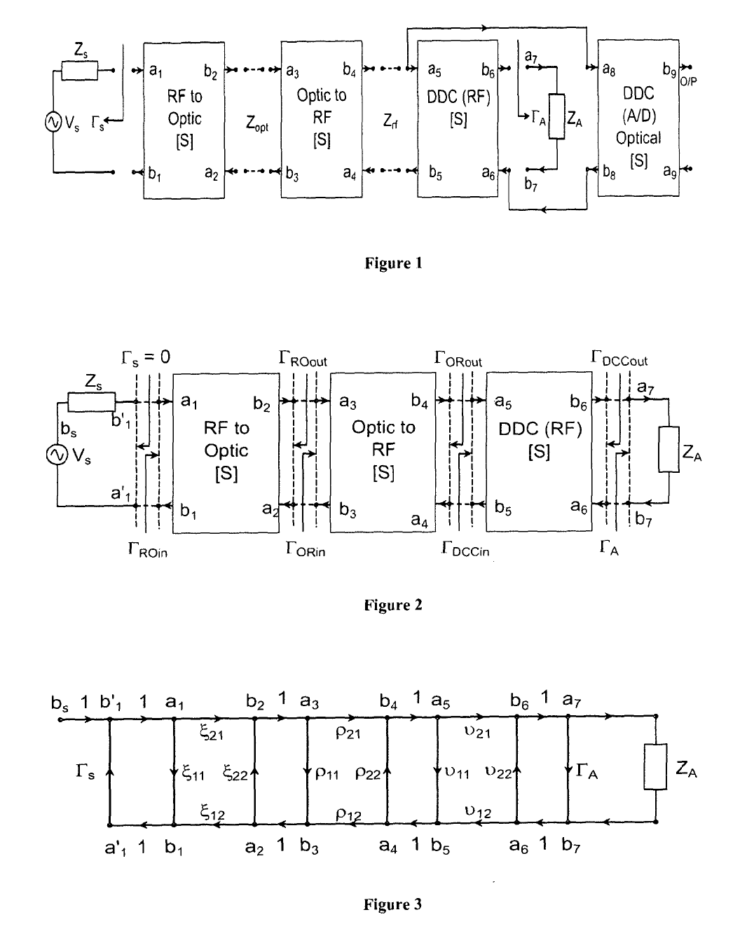

The DDC (A/D) converts the measured signals received from the DDC (RF) to a digital stream, prepared to be transmitted over an optical fibre. The DDC (A/D) is assumed to be perfectly matched to the DDC (RF) since the paths a₅ to a₈ and b₈ to a₆ are optical signals and the paths are isolated from the RF modules. Therefore the DDC (A/D) component is not needed to determine the scattering parameters of the HRS. This simplifies the system network, as shown in FIG. 2, and the subsequent analysis. The optical interface between the RF to Optical module and the Optical to RF module is assumed to be matched by the line impedance Zₒₚₜ. The interface between the Optical to RF module and the DDC (RF) is also assumed to be matched by the line impedance Z_{rf}.

Referring to the signal flow chart in FIG. 3, the scattering parameters for the RF to Optical module, Optical to RF module and the DDC (RF) module are denoted by ζ, ρ and ν respectively. Two additional nodes, a′₁ and b′₁, and a number of loss less connections are introduced into the signal flow chart to aid with the mathematical analysis.

The signal flow chart can be reduced by process of repetitive decomposition to find the ratio a₁÷bs, given in Equation 1.1. This expression can then be used to determine the signal delivered to the input of the HRS (a₁) as a function of the entire network scattering parameters and the input source signal Vs. One can assume that the path taken by the optical signal cannot produce RF reflections, therefore Γ_{ROout}=Γ_{ORin}=0 and Eqn. 1.1 can be reduced to equation 1.2.

$$\begin{matrix}\frac{{a}_{1}}{{b}_{s}} = \frac{1}{1 - {Γ}_{s} \{ {ζ}_{11} + \frac{{ζ}_{21} {ζ}_{12} \{ \begin{matrix}{ρ}_{11} + \\ \frac{{ρ}_{21} {ρ}_{12} \{ {v}_{11} + \frac{{v}_{21} {v}_{12}}{1 - {v}_{22} {Γ}_{A}} \}}{1 - {ρ}_{22} \{ {v}_{11} + \frac{{v}_{21} {v}_{12}}{1 - {v}_{22} {Γ}_{A}} \}}\end{matrix} \}}{1 - {ζ}_{22} \{ \begin{matrix}{ρ}_{11} + \\ \frac{{ρ}_{21} {ρ}_{12} \{ {v}_{11} + \frac{{v}_{21} {v}_{12}}{1 - {v}_{22} {Γ}_{A}} \}}{1 - {ρ}_{22} \{ {v}_{11} + \frac{{v}_{21} {v}_{12}}{1 - {v}_{22} {Γ}_{A}} \}}\end{matrix} \}} \}} & Eqn 1.1 \\ \frac{{a}_{1}}{{b}_{s}} = \frac{1}{1 - {Γ}_{s} \{ {ζ}_{11} + {ζ}_{21} {ζ}_{12} \frac{{ρ}_{21} {ρ}_{12} \{ {v}_{11} + \frac{{v}_{21} {v}_{12}}{1 - {v}_{22} {Γ}_{A}} \}}{1 - {ρ}_{22 } \{ {v}_{11} + \frac{{v}_{21} {v}_{12}}{1 - {v}_{22} {Γ}_{A}} \}} \}} & Eqn 1.2\end{matrix}$$

The input reflection coefficient of the HRS can be expressed as equation 1.3 and reduced using the preceding assumption to equation 1.4.

$$\begin{matrix}{Γ}_{HRSin} = \frac{{b}_{1}}{{a}_{1}} = {ζ}_{11} + \frac{{ζ}_{21} {ζ}_{12} \{ {ρ}_{11} + \frac{{ρ}_{21} {ρ}_{12} \{ {v}_{11} + \frac{{v}_{21} {v}_{12}}{1 - {v}_{22} {Γ}_{A}} \}}{1 - {ρ}_{22} \{ {v}_{11} + \frac{{v}_{21} {v}_{12}}{1 - {v}_{22} {Γ}_{A}} \}} \}}{1 - {ζ}_{22} \{ {ρ}_{11} + \frac{{ρ}_{21} {ρ}_{12} \{ {v}_{11} + \frac{{v}_{21} {v}_{12}}{1 - {v}_{22} {Γ}_{A}} \}}{1 - {ρ}_{22} \{ {v}_{11} + \frac{{v}_{21} {v}_{12}}{1 - {v}_{22} {Γ}_{A}} \}} \}} & Eqn 1.3 \\ {Γ}_{HRSin} = \frac{{b}_{1}}{{a}_{1 }} = {ζ}_{11} + {ζ}_{21} {ζ}_{12} \frac{ {ρ}_{21} {ρ}_{12} \{ {v}_{11} + \frac{{v}_{21} {v}_{12}}{1 - {v}_{22} {Γ}_{A}} \}}{1 - {ρ}_{22} \{ {v}_{11} + \frac{{v}_{21} {v}_{12}}{1 - {v}_{22} {Γ}_{A}} \}} & Eqn 1.4\end{matrix}$$

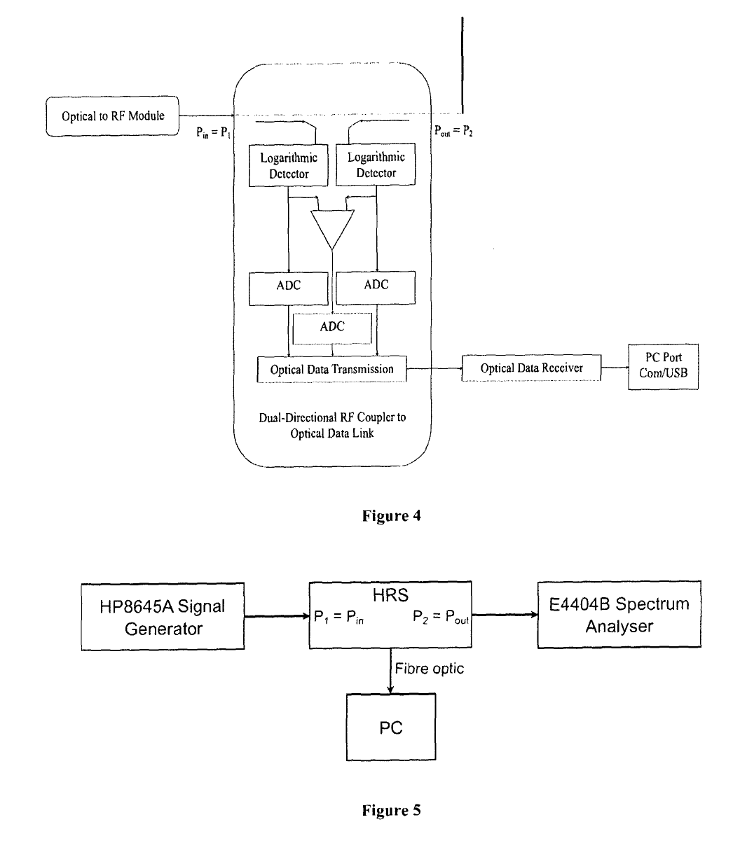

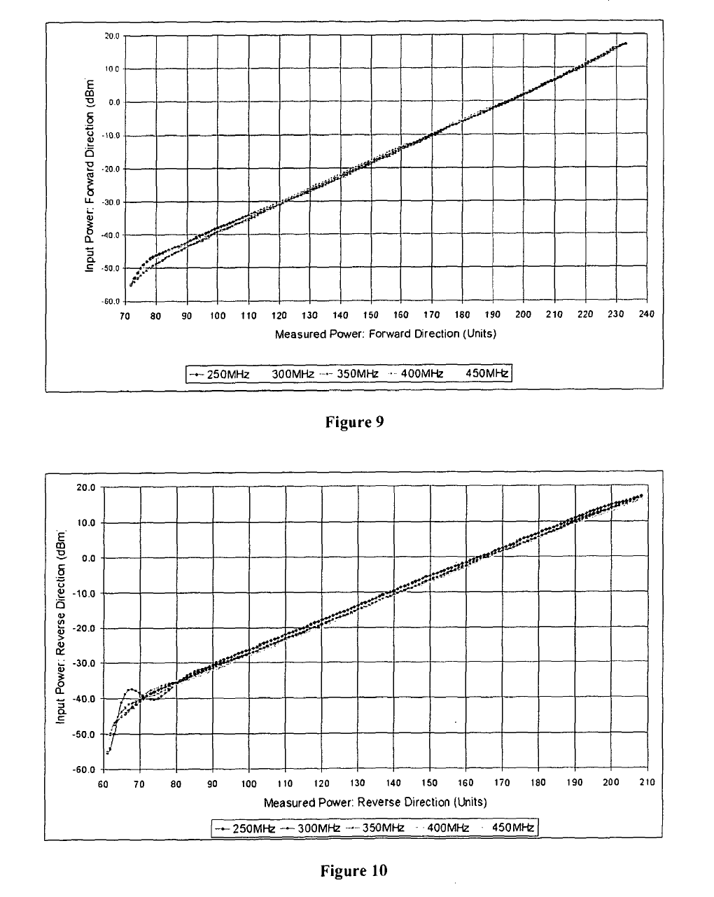

FIG. 4 shows a system diagram of the HRS. The HRS was mounted within a die-cast box to isolate it from external effects. The input port, Pᵢₙ≡P₁, was connected to the Hewlett Packard 8645A signal generator, which was calibrated to take account of the losses in the cable. The output port, Pₒᵤₜ≡P₂, was connected to the input port of an E4404B spectrum analyser. The digital data was transferred to the Personal Computer (PC) via a fibre-optic cable. The forward power, reverse power and reflection coefficient is represented by an integer which is displayed on a monitor. The measurement set-up for forward power is shown in FIG. 5. In theory the HRS is a reciprocal device, however a small amount of asymmetry was found. The ports were chosen to give the best impedance match at the port that is connected to the antenna. The measurements were done at five discrete frequencies: 250 MHz, 300 MHz, 350 MHz, 400 MHz and 450 MHz. The linearity of the output data to the input power for both the forward and reverse direction is shown in FIG. 9 and FIG. 10, respectively, and represents the input power (unit) for a given input power dB at each frequency. The data can be used in a lookup table to determine the power travelling into either P₁ or P₂. It is important to know the amount of power travelling into both P₁ and P₂; the power delivered to the antenna can be determined (taking into account the insertion loss of the HRS) from the power travelling into P₁ and the reflected power from the antenna can be determined from the power travelling into P₂.

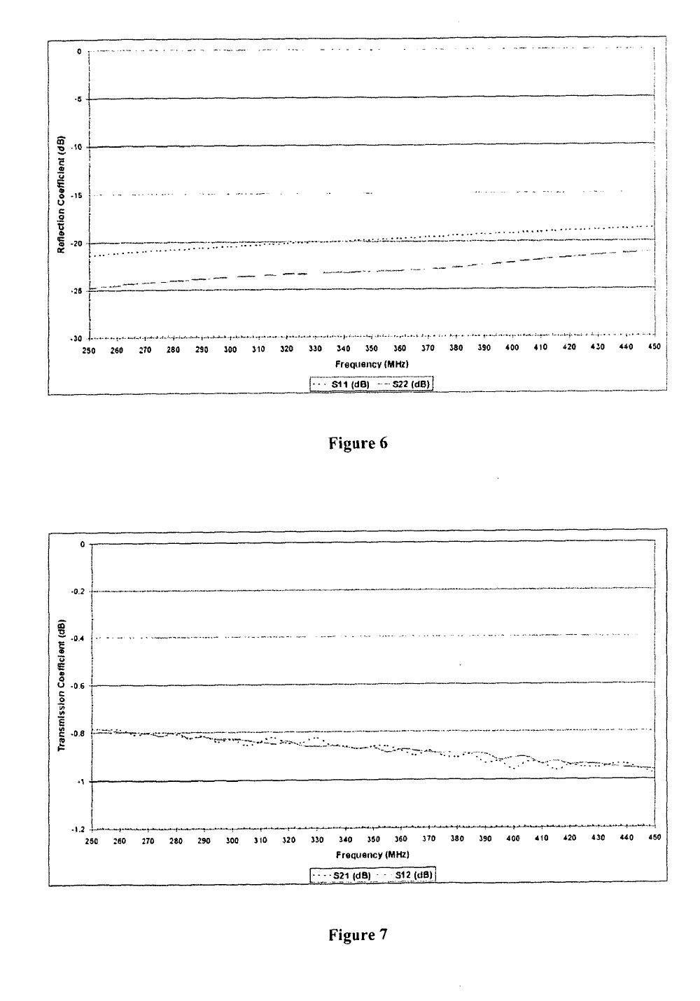

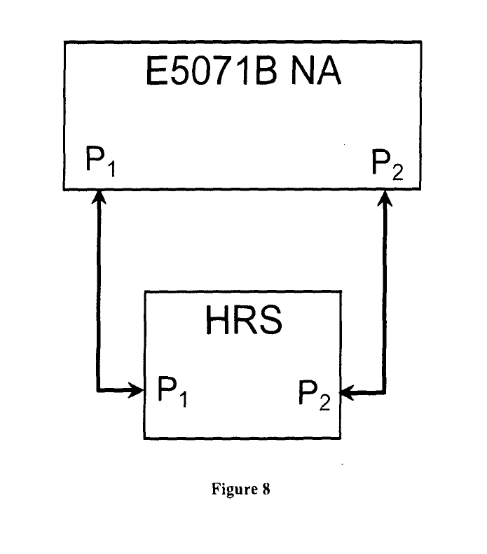

The HRS was also characterised by measuring its scattering parameters using a network analyser, as shown in FIG. 8. At 350 MHz the scattering parameters are: S₁₁(−19.8 dB 58Ω), S₂₁ (−0.86 dB), S₁₂(−0.86 dB) and S₂₂ (−23.190 52Ω). The reflection and transmission coefficient for the HRS are shown in FIG. 6 and FIG. 7, respectively. The HRS has a good match at both ports and an acceptable insertion loss of less than 1 dB.

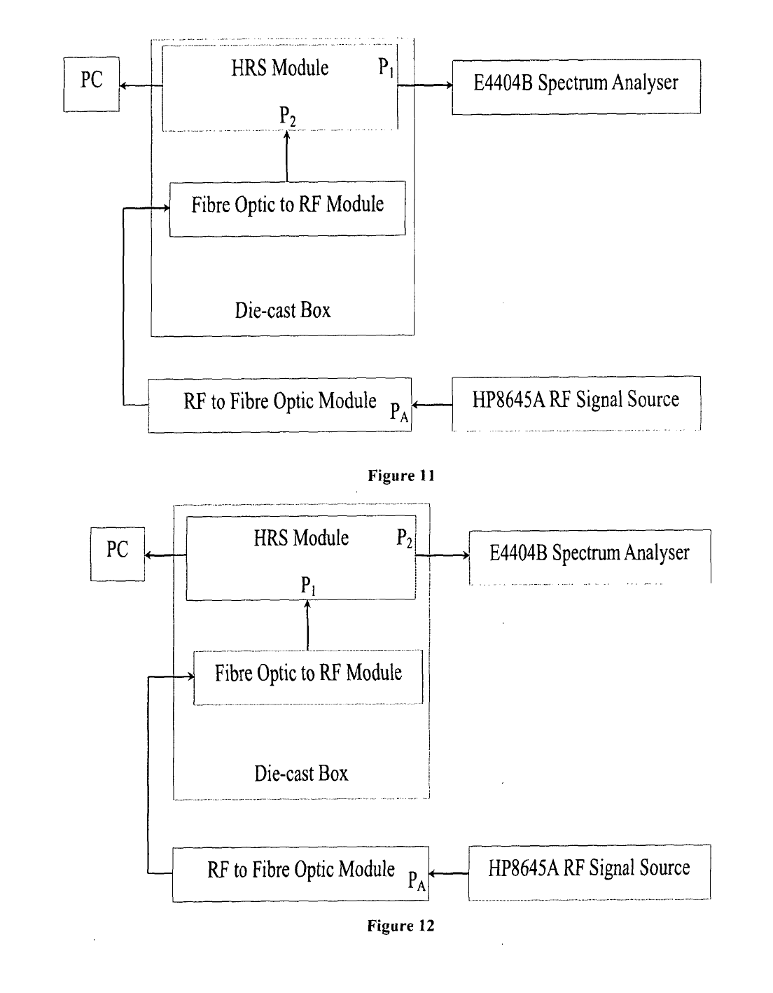

FIGS. 11 and 12 show the HRS equipment set up for calibration of the HRS with Fibre Optic to RF module. To characterise the HRS measurement system the RF input power to the RF to Fibre-Optic Module and the corresponding RF and digital data form must be known. The HRS and the Fibre Optic to RF Module were both mounted into a die-cast box to isolate the two modules from external effects and enable the calibration of the combined modules. The HRS was set-up in the normal mode of operation with power being delivered to P₁ and received at P₂. The RF to Fibre Optic Module converts the RF power received at its input port, P_{A}, to an optical signal which is transmitted to the Fibre Optic to RF module, which converts the optical signal to RF before transmitting it to the HRS. The output at P₂ of the HRS is measured by the E4404B spectrum analyser and the corresponding numerical values are recorded on a PC. This calibration was also done with the HRS set-up in the reverse mode with power being delivered to P₂ and received at P₁. The calibrated data was then used in a lookup table to determine the measured input and reflected power in dBm. The reason for calibrating the HRS in reverse mode was to obtain calibration data for the reflected power from the output port, P₂, as this is the port that is connected to the antenna.

The Fibre-Optic to RF Module is operated in saturation to generate the maximum output power of 10 dBm at 350 MHz. The output port of this module is connected directly to the HRS input port, P₁. The HRS has a nominal insertion loss of 1.2 dB, thus 8.8 dBm is presented at its output port, P₂. This agrees with the scattering parameter measurements of the HRS, given in paragraph two of page 14, showing that the S₂₁ is approximately 0.9 dB, and gives confidence in the calibration process.

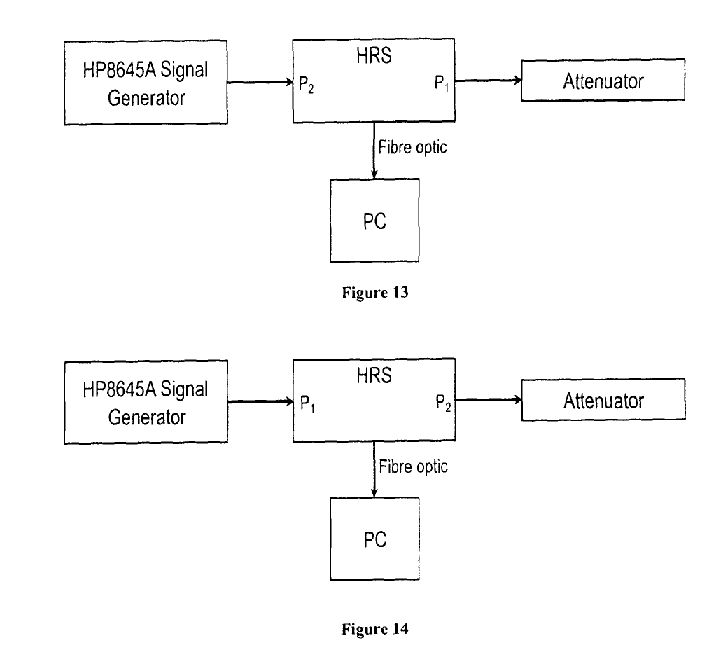

FIGS. 13 and 14 show the equipment set-up for calibrating the HRS to measure return loss. The HRS requires calibration to ensure that the measured reflected power from the antenna, which is received at P₂ of the HRS, is calibrated against a known return loss. This was done by measuring the return loss of several calibrated attenuators. The attenuators range from 1 dB to 20 dB, enabling calibration measurements covering the dynamic range of the HRS. The return loss of the attenuators is effectively doubled because the signal passes through the attenuator in the forward and then reverse direction, as it is reflected from the open end of the attenuator. The complex impedance and the reflection coefficient of an attenuator are functions of the terminating load, which is either short-circuit, open-circuit or matched (50Ω) and they take on the impedance characteristics of the termination. For an open-circuit termination the real/reactive part of the impedance tends to be high/capacitive. Whereas with a short-circuit termination the real/reactive part of the impedance tends to be low/inductive. It is important to know the impedance of the calibrated attenuators as an antenna's impedance varies depending upon the type of antenna. Typically, the reactance of electrically small dipole and loop type antennas are capacitive and inductive, respectively. The reflection coefficients, S₁₁, of the attenuators are shown in Table 1.

TABLE 1

| Attenuator | S₁₁ (dB) |
|---|---|
| A | −1.55 |
| B | −1.65 |
| C | −4.35 |
| D | −4.95 |
| E | −7.64 |
| F | −8.22 |
| G | −10.82 |
| H | −11.74 |
| I | −15.04 |
| J | −19.36 |
| K | −22.01 |
| L | −41.43 |

The measured digital data were then used in a lookup table to determine the return loss of an antenna. The calibration was done both with and without the Fibre Optic to RF Module. Therefore, where it is not convenient to use an optical feed to the HRS, calibrated S₁₁ measurements can be taken with a RF cable connected directly to the HRS. The reflection coefficient, S₁₁, can be measured to as low as −22 dB (when expressed in dB the S₁₁ varies from 0 dB with total mismatch to −∞dB with perfect match) when using the HRS alone. This figure deteriorates to −17 dB when the HRS is combined with the Fibre-Optic to RF Module. This is thought to be due to the mismatch between the two modules. The two modules are connected together by a short wire connection. At this stage no attempt was made to impedance match the connection as the level of measured reflection coefficient is acceptable as it is within the typical refection coefficient values for electrically small antennas that are at best −10 dB.

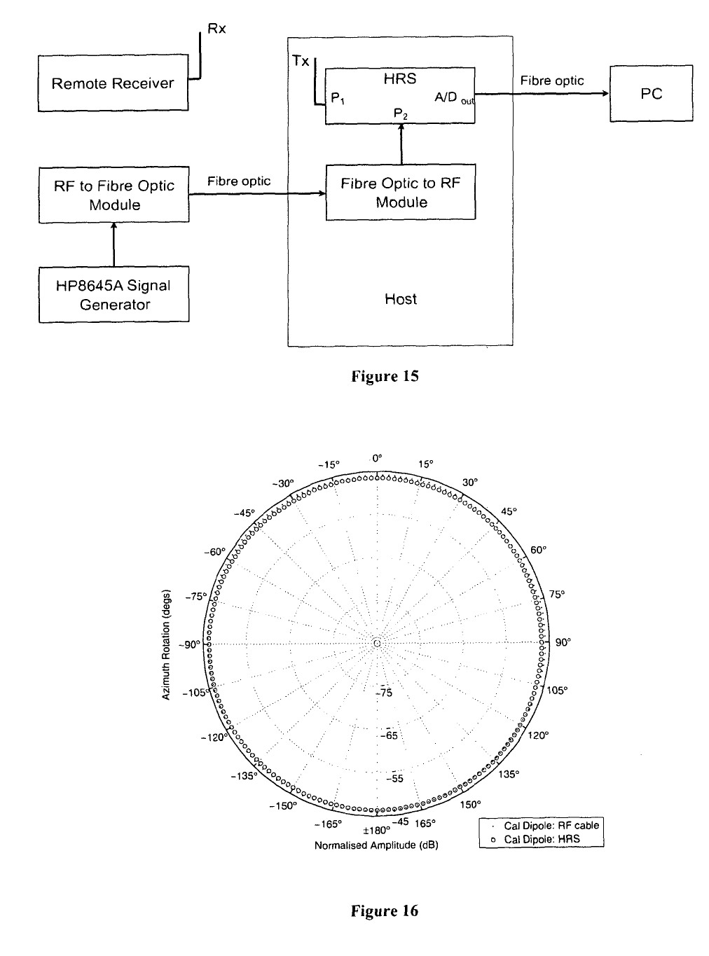

FIG. 15 illustrates the HRS integrated into an antenna radiation measurement system. The HRS was integrated into a measurement system which is used to plot the radiation pattern of an antenna. When measuring the radiation pattern of electrically small antennas, where the impedance match is known to be very poor, most of the RF energy delivered to the antenna is reflected along the cable back to the source, and a small percentage of energy is radiated from the antenna. The reflected energy is then radiated over the length of the cable and is detected by the receive antenna. This adverse effect is eliminated by incorporating the RF over fibre module into the measurement system. The HRS is also integrated into the measurement system to ensure that its effect is measured, as it may ultimately be part of an embedded antenna and beacon system or other communications system. Referring to FIG. 15 the RF signal from the signal generator travels through the RF to Fibre Optic Module which converts it into an optical signal. The optical signal is then delivered to the host via a fibre optic cable (the host is now isolated from the RF source signal) where the Fibre Optic to RF Module converts it to RF. The function of the HRS module is to measure and feed the RF signal to the transmit antenna (Tx), and measure the reflected RF signal from the Tx; convert these RF signals to a digital stream before transmitting them to a PC over a fibre-optic data cable. The RF energy radiated from the Tx is received by a separate calibrated log-periodic receive antenna (Rx) to confirm measurements collated by the HRS.

FIG. 16 shows two radiation patterns, one for a dipole antenna connected directly to a RF cable and the other for the dipole antenna connected to the HRS. The HRS was used to measure several antennas to ensure that the measurements were consistent and not specific to a particular type of antenna. These measurements enable the investigation of cable and ground effects on antenna performance, and how best to mitigate the adverse effects which may arise from the near-field environment.

Five antennas were measured:

1. Calibrated dipole

### 2. Monopole 1 (M1)

### 3. Monopole 2 (M2)

### 4. Monopole 3 (M3)

### 5. Electrically Small Patch (ESP)

Each antenna was measured in the conventional manner with a RF cable connected directly to the antenna and then by using the HRS. The calibrated dipole was used as a reference antenna as it has a well understood radiation pattern (dipoles exhibit a uniform radiation pattern in the plane orthogonal to its polarisation). The dipole was tuned to 350 MHz, S₁₁=−18 dB and the radiation pattern of the vertically polarised dipole was then measured using a far-field antenna range. The radiation patterns show that for a well tuned antenna the RF over fibre-optic system is not required as very little RF energy is reflected back to the source. The RF energy reflected along the cable from the dipole is just 1.6% of the RF energy delivered to it. The power delivered to the antenna is 8.5 dBm, therefore the reflected power is −0.5 dBm.

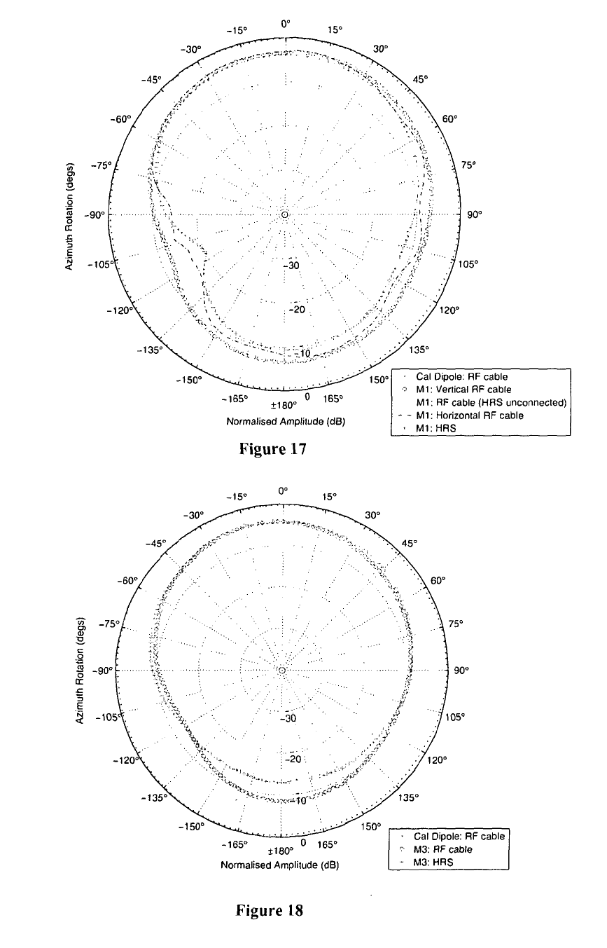

M1 and M3 are monopoles set parallel to a ground-plane, M3 is a similar construction to M1 but with a smaller ground plane. M1 has a reasonable match at 350 MHz of S₁₁=−12.5 dB and was used to assess the performance of HRS when measuring side lobe levels. M3 has a slightly smaller ground plane but was designed to have a better match, with a S₁₁=−20.5 dB with less than 1% of the energy reflected back to the RF source. M3 was used to show the advantage of using the HRS with very well matched antennas. Referring to the radiation plot for M1, shown in FIG. 17, little effect is observed on the radiation pattern when the antenna is connected to a vertically orientated RF cable or when the HRS is placed behind the ground-plane (HRS unconnected). This is expected as the antenna is tuned to the operating frequency and the HRS module simply becomes part of the ground plane. The RF energy reflected back to the antenna is 5.6%, (−4 dBm), of the RF energy delivered to it. Therefore a small amount of this reflected energy will be radiated by the cable. An improvement is seen in the fidelity of the side lobes when the RF cable is set horizontal to the antenna. This shows that the RF radiation from the cable contributes to the far-field radiation pattern of the antenna and that its influence can be somewhat mitigated by positioning the cable orthogonal to the polarisation of the antenna; in this case the antenna is polarised vertically and the cable horizontally. Further improvement is seen when the HRS is used to isolate the antenna from the RF source. Isolating the antenna in this way significantly reduces systematic measurement error and ensures that the measured far-field radiation pattern is that of the antenna and not the measurement system. The radiation plot for M3 is shown in FIG. 18 reveals that even with a very well matched antenna the RF cable radiates RF energy and that the HRS is capable of reducing the back-lobe and improving the sensitivity of the measurement system.

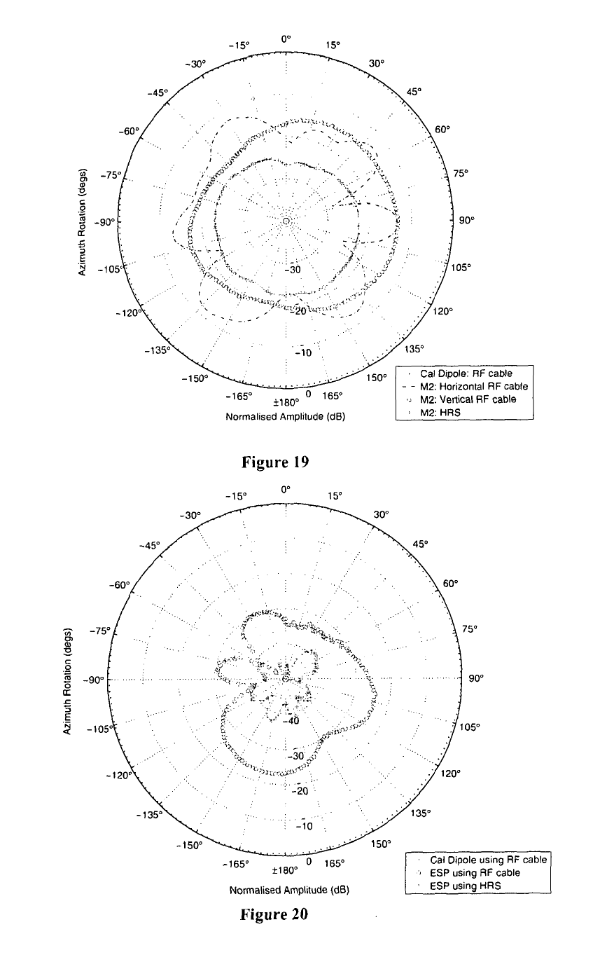

The M2 antenna is an electrically small monopole without a ground-plane, having a poor match at 350 MHz of S₁₁=−1.5 dB such that 70% (7 dB here) of the delivered power is reflected back to the source. Referring to the plot shown in FIG. 19, directly connecting a vertically positioned RF cable to the antenna shows that the reflected power from the antenna is radiated along the cable and is measured in the far-field as nulls and peaks. However, when the RF cable is positioned vertically and concentric to the axis of the monopole the radiation from the cable is less prominent, being more evenly distributed in the vertical plane. As with M1 and M3, an improvement is seen when the HRS is used to isolate the antenna from the RF source. The radiation from the antenna is 10 dBm lower than that measured by the conventional method.

The ESP antenna is a patch antenna which was originally designed for GPS applications operating at 1.575 GHz. The patch antenna is electrically small when operated at 350 MHz. At this frequency the S₁₁=−0.03 dB, consequently 99:3% of the energy is reflected back to the source and very little energy is radiated by the antenna. It differs significantly from the previously measured antennas and shows that the HRS can be used for various types of ESA. As with M1, M2 and M3 the radiation plot for the ESP shows that the RF cable radiates the reflected energy and that this is mitigated by using the HRS, as seen in FIG. 20. At certain angles the actual radiated power is much lower, 15 dBm, than that measured by the conventional method.

These measurements have shown that the HRS can be integrated with the RF fibre optic measurement system to improve the sensitivity of ESA radiation pattern measurements. The measurements provide a baseline for reflection coefficient measurements of host-embedded antennas using the HRS. The measurement system effectively isolates the antenna from the RF source while enabling the measurement of the reflection coefficient. Consequently, the radiation from the antenna rather than the RF cable is measured. The difference in the measured signal when using the HRS measurement system and conventional methods varies depending on the type of antenna; for an ESA this can be as much as 15 dB. The system can also be used for different types of ESA. As stated previously the electrically small reflectometer used as part of the HRS should ideally be electrically smaller than the ESA being measured.

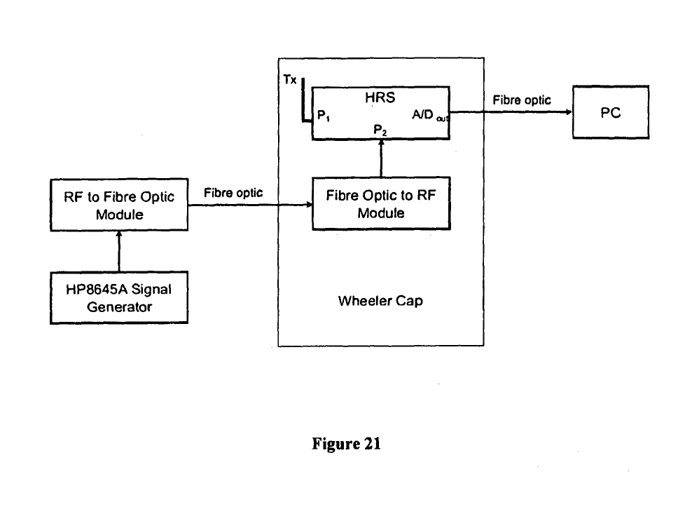

FIG. 21 is a system diagram of the HRS integrated into a Wheeler Cap measurement system. The reason for integrating the HRS and Fibre Optic to RF Module in to the Wheeler Cap is to enable repeatable efficiency measurements of host-embedded antennas and provide a benchmark for antennas developed in the future. The HRS and Fibre Optic to RF Module are integrated into the Wheeler Cap to measure the reflection coefficient of the isolated antenna. The efficiency of the antenna can then be determined by combining the results of this measurement with the antenna's measured free space reflection coefficient. Fibre optic cables are used to interface with the Wheeler Cap. The RF signal is generated from within the Wheeler Cap, thus isolating the Wheeler Cap from the external RF source. To calculate the efficiency of an ESA both the free space and shielded complex reflection coefficients must be measured. At this stage only the magnitude of the reflection coefficient is measured with the HRS, the phase is reconstructed by differentiating the magnitude with respect to frequency. The phase reconstruction error was determined by applying the differentiation process to the measured Vector Network Analyser reflection coefficient for each antenna. The phase reconstruction error was then used as the correction factor for the HRS measurements. The reflection coefficient magnitude and reconstructed phase was then used to determine the complex input impedance Z_{A}, of the antenna. The efficiency of the antenna η was then determined by substituting the real part of the impedance from the free space and Wheeler Cap measurements using equation 1.5, where Rᵣ is the radiation resistance, R_{L} is the loss resistance, R_{fs} the free space resistance and R_{cap} the Wheeler Cap resistance within the system. The HRS needs to be developed further to enable phase measurements to be undertaken, thus enabling the true efficiency of the antenna to be determined.

$$η = \frac{{R}_{r}}{{R}_{r} + {R}_{L}} = 1 - \frac{{R}_{cap}}{{R}_{fs}} \qquad Eqn 1.5$$

The S₁₁ of M1, M2, M3 and the ESP were taken in free space with and without a RF feed-cable. The feed-cable, which is 61 cm in length, positions the antenna in the centre of the Wheeler Cap; without it the antenna would be placed against the top surface, which would act as a ground plane and possibly give rise to spurious readings. Although the operating frequency is 350 MHz it is beneficial to know what happens to the resonant frequency over a wider bandwidth. Therefore the measurements were taken from 345 MHz to 355 MHz. Two separate measurements were undertaken and the results compared; one using a VNA and the other using the HRS. In both cases, the measurements were undertaken with the antennas in free space and then placed in the Wheeler Cap. A lookup table is used to calculate the S₁₁ measurements from the HRS. A linear gradient calibration factor is used to calibrate the HRS to the specific antenna. The Fibre Optic to RF Module is used to effectively isolate the antenna from the RF source. The effects of this isolation on the match of the antenna have hitherto been unknown as they could not be measured. The HRS is used to measure the reflection coefficient of the antenna, revealing the impact made on the performance of the antenna.

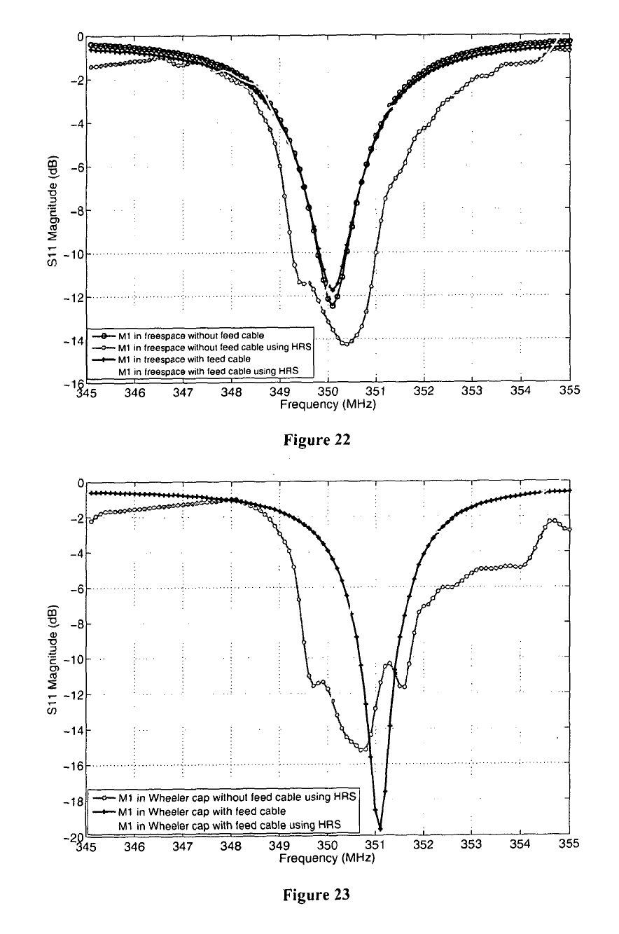

M1 is a narrow-band resonant antenna (resonant antennas are tuned to an operating frequency and tend to be narrowband), which has a bandwidth of 0.2% [the bandwidth being taken to equal 100×(upper frequency−lower frequency)/Centre frequency], however, the bandwidth is increased to 0.5% by isolating the antenna and measuring the S₁₁ using the HRS as shown in FIGS. 22 and 23. It is possible that the HRS is acting as a tuning circuit. Nevertheless, the embedded antenna would include this module if it became part of a beacon system.

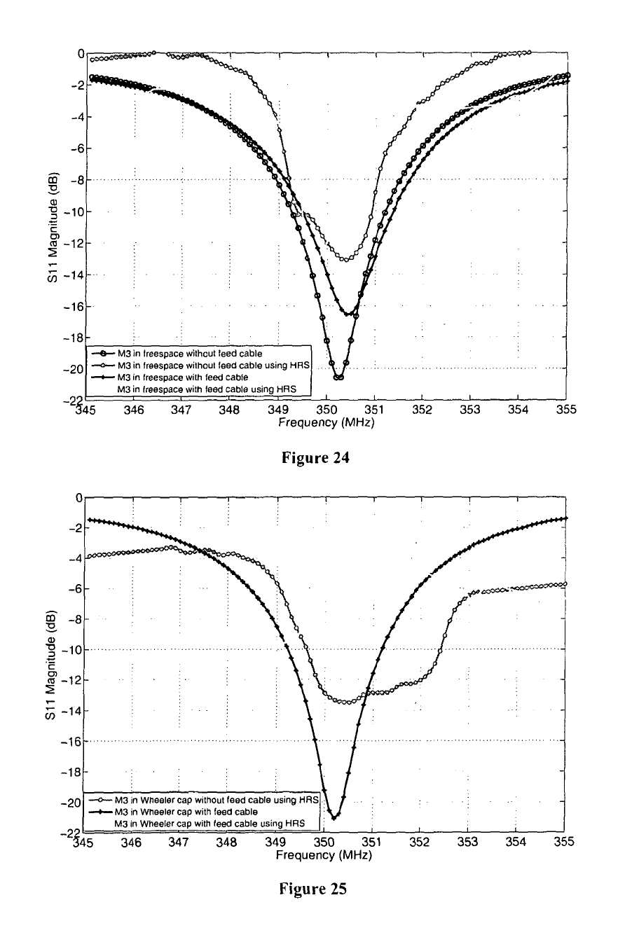

FIGS. 24 and 25 show the reflection coefficient measurements for M3, which is a similar type of antenna to M1. For both these antennas the bandwidth is widened by using the HRS.

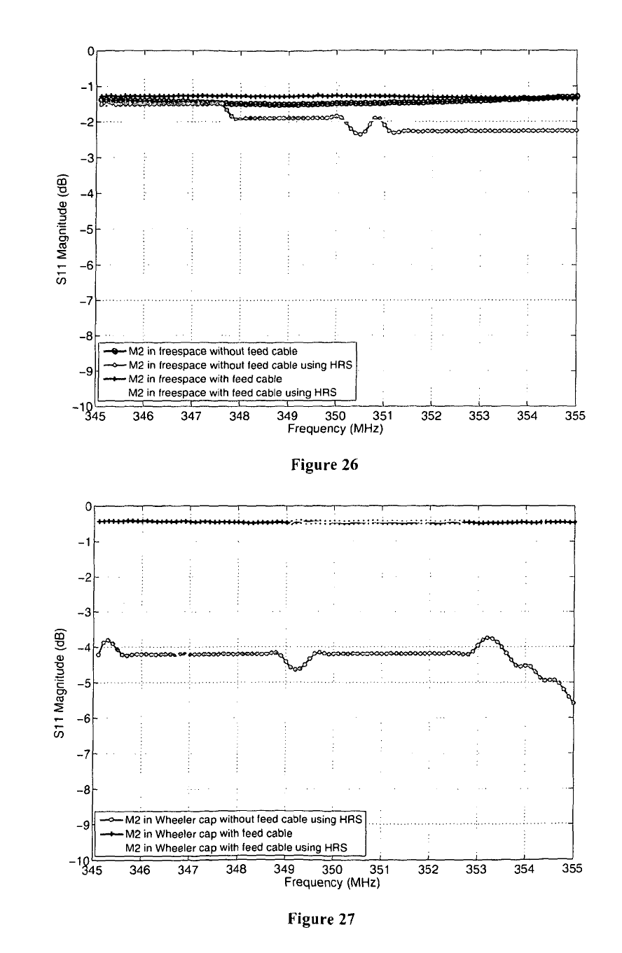

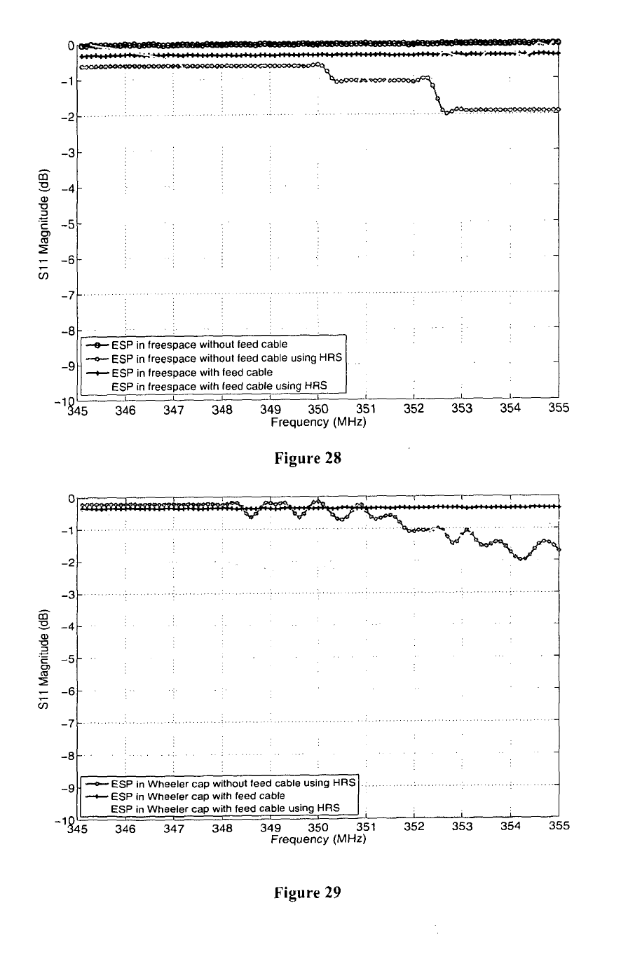

The free space and Wheeler Cap reflection coefficient measurements for antennas M2 and ESP are shown in FIGS. 26 to 29 respectively. When the antenna is placed in the Wheeler Cap, the influence of the feed-cable is clearly seen. Therefore, when measuring ESA's it is essential to ensure that the Wheeler Cap is isolated from the measurement system. These measurements have shown that the HRS can be used to measure the reflection coefficient of a host-embedded antenna while effectively isolating it from the RF source. With well tuned antennas the benefit gained from isolating the antenna in this way is increased impedance bandwidth which translates into more signal power being radiated by the antenna. The measurements also show that the system can be integrated into a Wheeler Cap to undertake antenna efficiency measurements. Furthermore, these measurements provide a baseline for radiation efficiency measurements of host-embedded antennas using the HRS.

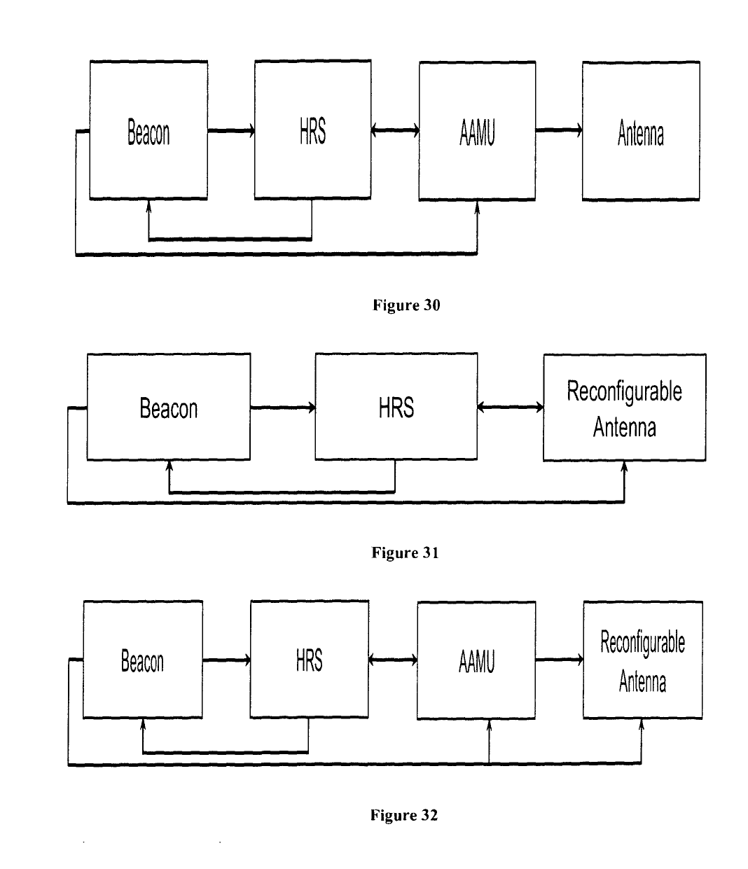

FIGS. 30 to 32 show system diagrams of various ways the HRS can be configured into a beacon system but this is not intended to be limiting. A person skilled in the art will appreciate that the HRS can be used in any communications system. In fact part of the rational, underpinning the development of the HRS is based on the concept of being able to retune beacon antennas to adapt to differing environments. This improves the efficiency of beacon antennas which may be deployed in different environments, as the antenna detunes with a change in environment. This is done by enabling the beacon system to dynamically adapt to its environment, thus operate at optimum efficiency. These adaptive techniques have been used in large-scale systems. A beacon system can be embedded into a host and can be configured in a number of ways.

1. The beacon controls the AAMU within a feedback loop. The AAMU is then attached to a non-reconfigurable antenna.
2. The beacon controls a reconfigurable antenna within a feedback loop.
3. The beacon controls both the AAMU and the reconfigurable antenna within a feedback loop. The HRS is used to monitor the forward and reverse signal parameters. This information is fed back to the beacon processor, which is used to assess the match of either the AAMU or the reconfigurable antenna, depending on the configuration used. The beacon then sends commands to optimise the match of the antenna by either modifying the AAMU or by adjusting the reconfigurable antenna. The third configuration is where both the AAMU and the reconfigurable antenna is used in a closed loop system to retune the beacon to the operating frequency. In this type of system the AAMU and the reconfigurable antenna may be tuned simultaneously and in near real-time. The choice of which configuration to use for a particular host will be determined by several factors, which will include the size of the host, the type of antenna to be used and the amount of space available inside the host. Antennas which are embedded in hosts are generally electrically small, making them sensitive to the surrounding environment and vulnerable to detuning. Furthermore, any measurement system placed close to the antenna element acts as a parasitic element becoming part of the antenna. The design challenge is to measure the forward and reverse signals without compromising the antenna. This is done by effectively isolating the measurement system from the antenna, thus preventing the measurement system from becoming part of the antenna. The reconfigurable antenna is an integral part of the beacon system and has the ability to change most of its parameters in real-time; it therefore has the ability to be tuned over a required frequency bandwidth. Its ability to reconfigure also allows the antenna to change its polarisation state to almost any desired polarisation state, from Right Hand Circular Polarisation, Left Hand Circular Polarisation to linear polarisation, while optimising its impedance match, thus improving the overall efficiency of the system. A person skilled in the art will appreciate that the HRS can be configured for use in other types of communications systems and not just a beacon system.

1. A test and measurement system for measuring radio frequency signals transmitted or received by an electrically small radiating element comprising an electrically small reflectometer wherein the output from the electrically small reflectometer is provided in the form of an optical digital signal.

2. A test and measurement system according to claim 1 wherein the electrically small reflectometer comprises a radio frequency dual directional coupler electronically connected to an analogue to digital converter.

3. A test and measurement system according to claim 1 wherein the system further comprises an optical data transmitter module.

4. A test and measurement system according to claim 3 wherein the system further comprises an optical data receiver.

5. A test and measurement system according to claim 1 wherein the system further comprises an optical to radio frequency module.

6. A test and measurement system according to claim 1 wherein the system is located within an anechoic chamber or far-field antenna measurement range.

7. A test and measurement system according to claim 1 wherein the system is located within a wheeler cap.

8. A radio frequency device comprising a test and measurement system according to claim 1.

9. A communications system comprising a test and measurement system according to claim 1.

10. (canceled)
